(19) United States
(12) Patent Application Publication
(10) Pub. No.: US 2020/0194609 A1
(43) Pub. Date: Jun. 18, 2020

(54) SOLAR CELL WITH ZINC CONTAINING BUFFER LAYER AND METHOD OF MAKING THEREOF BY SPUTTERING WITHOUT BREAKING VACUUM BETWEEN DEPOSITED LAYERS

(71) Applicant: BEIJING APOLLO DING RONG SOLAR TECHNOLOGY CO., LTD, Beijing (CN)

(72) Inventors: Rouin Farshchi, Palo Alto, CA (US); Geordie Zapalac, Santa Cruz, CA (US); Timothy Nagle, Campbell, CA (US); Weijie Zhang, San Jose, CA (US); Jochen Titus, Sunnyvale, CA (US)

(21) Appl. No.: 16/223,945

(22) Filed: Dec. 18, 2018

(51) Int. Cl. H01L 31/0749; H01L 31/18; H01L 31/0224; H01L 31/0336; C23C 14/06; C23C 14/34; C23C 14/08

(52) U.S. Cl. CPC H01L 31/0749; H01L 31/1884; H01L 31/022483; C23C 14/086; H01L 31/18; C23C 14/0629; C23C 14/34; H01L 31/0336

(57) ABSTRACT

A method of manufacturing a solar cell including depositing a first electrode over a substrate under vacuum, depositing at least one p-type semiconductor absorber layer over the first electrode without breaking the vacuum, where the p-type semiconductor absorber layer comprises a copper indium selenide (CIS) based alloy material, sputter depositing an n-type semiconductor layer over the at least one p-type semiconductor absorber layer to form zinc oxysulfide in the n-type semiconductor layer without breaking the vacuum, and depositing a second electrode over the n-type semiconductor layer without breaking the vacuum.

### BACKGROUND

The present disclosure is directed generally to solar cells and more specifically to solar cells including various Zn containing buffer layers and methods of making thereof.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (“CIGS”). CIGS is included in these cells as the p-type absorber layer.

Thin-film photovoltaic cells (also known as solar cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

### SUMMARY

According to various embodiments, provided is a method of manufacturing a solar cell, comprising depositing a first electrode over a substrate under vacuum, depositing at least one p-type semiconductor absorber layer over the first electrode without breaking the vacuum, wherein the p-type semiconductor absorber layer comprises a copper indium selenide (CIS) based alloy material, sputter depositing an n-type semiconductor layer from a target comprising at least zinc and sulfur the at least one p-type semiconductor absorber layer to form zinc oxysulfide without breaking the vacuum, and depositing a second electrode over the n-type semiconductor layer without breaking the vacuum.

Other embodiments include a solar cell containing a substrate, a first electrode located over the substrate, at least one p-type semiconductor absorber layer located over the first electrode, wherein the p-type semiconductor absorber layer comprises a copper indium selenide (CIS) based alloy material, an n-type semiconductor layer located over the at least one p-type semiconductor absorber layer and comprising Al-doped zinc oxysulfide having an Al doping density of at least 1×10¹⁷ cm⁻³, and a second electrode located over the n-type semiconductor layer.

### BRIEF DESCRIPTION OF THE DRAWINGS

FIG. 1A is a schematic vertical cross sectional view of a thin-film photovoltaic cell according to an embodiment of the present disclosure.

FIG. 1B shows n-type semiconductor layer 40 of the cell in FIG. 1A divided into two sublayers.

FIG. 1C is a plot of oxygen to oxygen plus sulfur ratio versus solar cell efficiency showing the effect of tuning the composition of the ZnOS sublayer 40a. Experimental data are indicated by CTS and simulations are indicated by SCAPS.

FIG. 1D shows n-type semiconductor layer 40 with an additional CdS sublayer 40c deposited under the ZnOS sublayer 40a.

FIG. 1E is a plot of wavelength vs. external Quantum Efficiency (QE) which shows how reducing the thickness of the CdS sublayer 40c increases QE of the solar cell.

FIG. 1F is a plot of normalized CdS sputtering power vs. efficiency showing a substantial improvement of solar cell 10 efficiency with an addition of a ZnOS sublayer on top of CdS sublayer 40c over a range of thicknesses.

FIG. 1G is a plot of normalized CdS sputtering vs. open circuit voltage showing the effect of adding a ZnOS sublayer on the open circuit voltage (Voc) of solar cell 10.

FIG. 1H is a plot of normalized CdS sputtering vs. short circuit current (Jsc) showing the effect of adding ZnOS sublayer(s).

FIG. 1I is a plot of normalized CdS sputtering vs. Fill Factor (FF) showing the effect of adding ZnOS sublayer(s).

FIG. 2A shows a variation of the n-type semiconductor layer in which sublayer 40d may include ZnMgO (i.e., Zn_{1-y}Mg_{y}O) instead of i-ZnO.

FIG. 2B shows the n-type semiconductor layer with an additional CdS sublayer 40c deposited below the ZnOS sublayer 40a.

FIG. 3 is a schematic top view diagram of a first exemplary modular deposition apparatus that can be used to manufacture the photovoltaic cell illustrated in FIG. 1A according to an embodiment of the present disclosure.

FIG. 4 is a schematic diagram of a second exemplary modular deposition apparatus that can be used to manufacture the photovoltaic cell illustrated in FIG. 1A.

FIG. 5 is a schematic top view diagram of an exemplary sealing connection unit according to an embodiment of the present disclosure.

FIG. 6A is a schematic diagram of the third processing module of the apparatuses shown in FIGS. 4 and 5 sub-divided into multiple processing submodules to separately create multiple sublayers in layer 40 of FIG. 1B.

FIG. 6B is a plot of ZnOS doping density vs. solar cell efficiency which shows a relationship between ZnOS sublayer thickness, doping density, and solar cell efficiency.

FIG. 7 is a block diagram illustrating a sputter deposition method according to various embodiments of the present disclosure.

### DETAILED DESCRIPTION

Traditionally, to form a p-n junction on top of the p-type CIGS layer, CIGS cells include an n-type layer that is formed from CdS. This CdS sublayer is commonly referred to as “buffer layer.” Since CdS can absorb shorter wavelength photons (e.g., photons in the range 400-600 nm), its use as a buffer can prevent these photons from being used by the cell to generate electricity. This can reduce the overall efficiency of the solar cell by reducing its quantum efficiency in the shorter wavelength range. Embodiments of the present disclosure include a buffer layer containing zinc oxysulfide which is used instead of or in addition to CdS in CIGS solar cells. Non-limiting advantages of one or more embodiments include improving the quantum efficiency and overall efficiency of solar cells.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element.

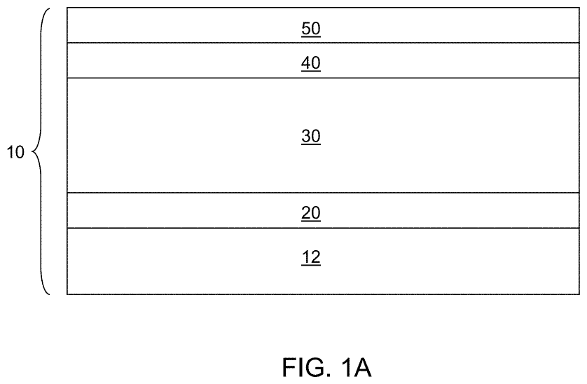

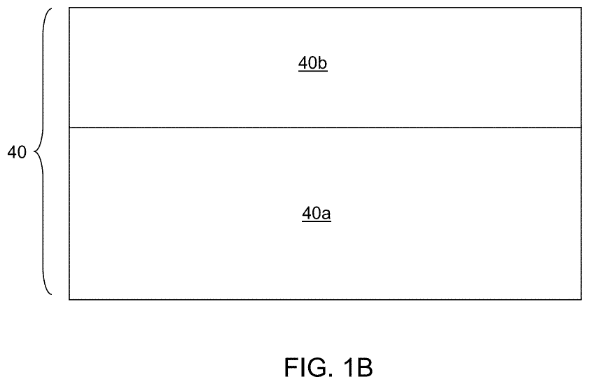

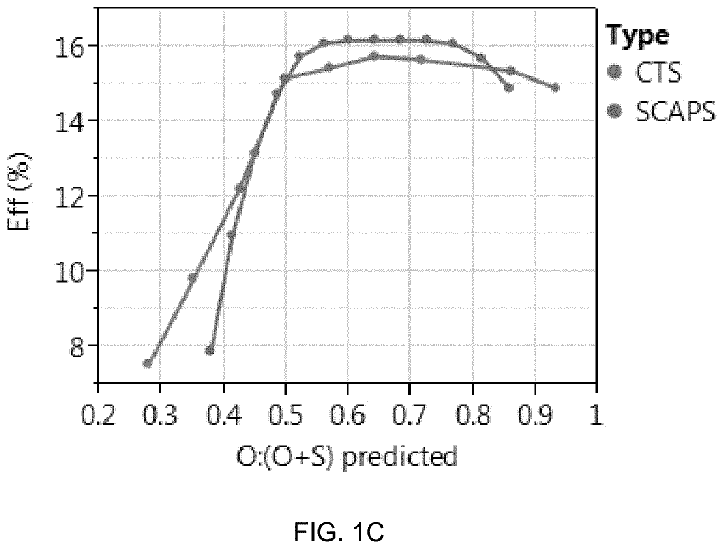

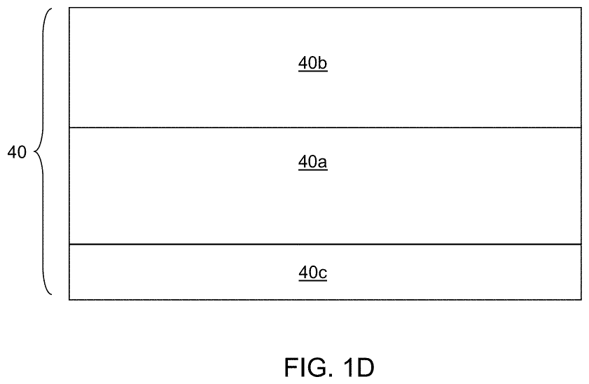

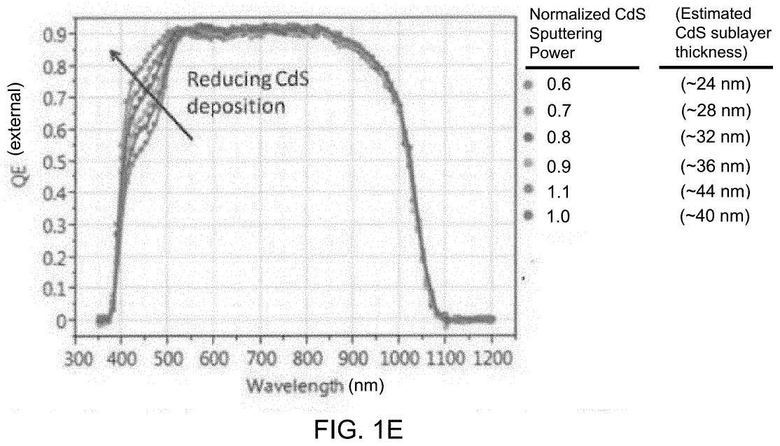

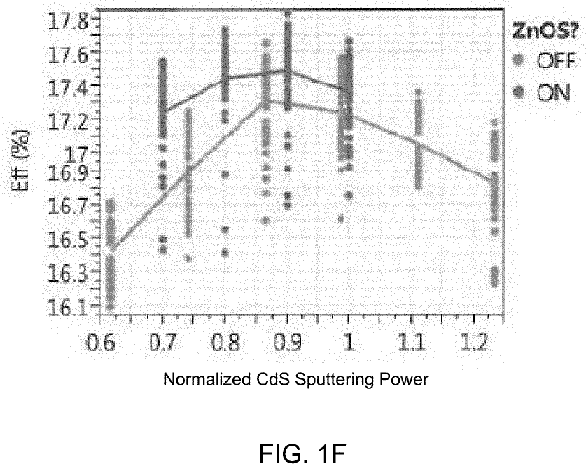

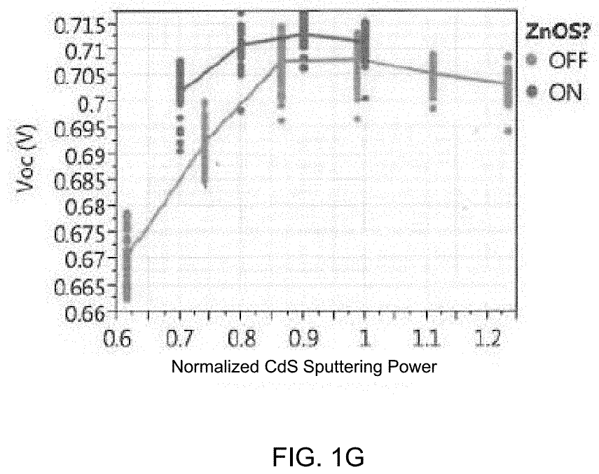

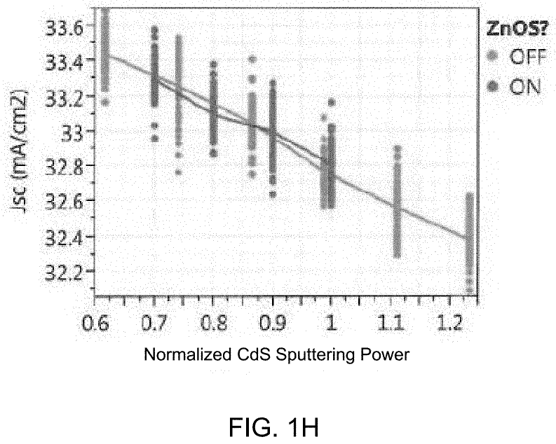

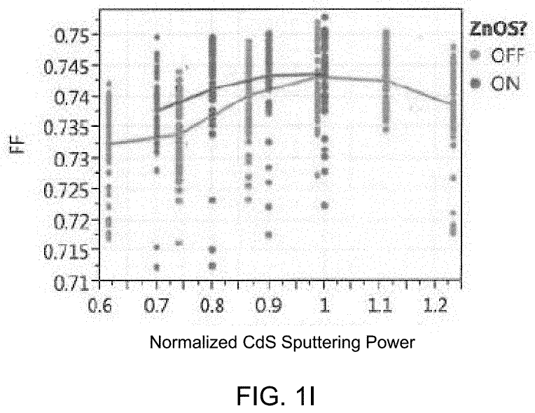

Referring to FIG. 1A, a vertical cross-sectional view of a photovoltaic cell 10 is illustrated. The photovoltaic cell 10 includes a substrate, such as an electrically conductive substrate 12, a first electrode 20, a p-type semiconductor layer 30, an n-type semiconductor layer 40, a second electrode 50, and an optional antireflective (AR) coating layer (not shown).

The substrate 12 is preferably a flexible, electrically conductive material, such as a metallic foil that is fed into a system of one or more process modules as a web for deposition of additional layers thereupon. For example, the metallic foil of the conductive substrate 12 can be a sheet of a metal or a metallic alloy such as stainless steel, aluminum, or titanium. If the substrate 12 is electrically conductive, then it may comprise a part of the back side (i.e., first) electrode of the cell 10. Thus, the first (back side) electrode of the cell 10 may be designated as (20, 12). Alternatively, the conductive substrate 12 may be an electrically conductive or insulating polymer foil. Still alternatively, the substrate 12 may be a stack of a polymer foil and a metallic foil. In another embodiment, the substrate 12 may be a rigid glass substrate or a flexible glass substrate. The thickness of the substrate 12 can be in a range from 100 microns to 2 mm, although lesser and greater thicknesses can also be employed.

The first or back side electrode 20 may comprise any suitable electrically conductive layer or stack of layers. For example, electrode 20 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. In another embodiment, the first electrode 20 can include a molybdenum material layer doped with K and/or Na, i.e., MoKₓ or Mo(Na,K)ₓ, in which x can be in a range from 1.0×10⁻⁶ to 1.0×10⁻². The electrode 20 can have a thickness in a range from 500 nm to 1 micron, although lesser and greater thicknesses can also be employed.

The p-type semiconductor layer 30 can include a p-type sodium doped copper indium gallium selenide (CIGS) layer or silver doped CIGS (Ag-CIGS) layer, as described in U.S. Patent Application Publication number US 2018/0158973 A1, published on Jun. 7, 2018 and incorporated herein by reference in its entirety. Layer 30 functions as a semiconductor absorber layer because it absorbs the bulk of the incident solar radiation. The thickness of the p-type semiconductor layer 30 can be in a range from 1 micron to 5 microns, although lesser and greater thicknesses can also be employed. The p-type semiconductor layer 30 can include one or more layers of CIGS. It may also include other suitable layers.

The n-type semiconductor layer 40 includes one or more n-type semiconductor materials or sublayers such as ZnOS, ZnMgO, CdS, and/or another metal oxide or a metal sulfide. Layer 40 is sometimes referred to as a “buffer” layer.

Relatively thick CdS sublayers employed in prior art CIGS solar cells often absorb short wavelength (e.g., 400 to 600 nm) photons. This absorption can reduce the quantum efficiency of the cell, especially in the blue photon regime. In certain embodiments, a monolithic CdS buffer layer (i.e., the n-type semiconductor layer) is replaced by one or more layers of wide bandgap compound semiconductor (e.g., ZnOS). As explained below, the electron affinity of the buffer layer has been shown to impact the efficiency of the solar cells.

As shown in FIG. 1A, in certain embodiments, n-type semiconductor layer 40 may be a monolithic, single layer of material such as doped or undoped zinc oxysulfide (“ZnOS”). Other alternatives are discussed in more detail below in which the n-type semiconductor layer 40 includes a ZnOS sublayer in addition to one or more other sublayers. The particular composition or stoichiometry of n-type semiconductor layer 40 may be influenced by processing parameters during layer deposition. The thickness of the n-type semiconductor layer 40 may be less than the thickness of the p-type semiconductor layer 30, and can be in a range from 20 nm to 100 nm, although lesser and greater thicknesses can also be employed.

The junction between the p-type semiconductor layer 30 and the n-type semiconductor layer 40 is a p-n junction. The n-type semiconductor layer 40 can be a material that is substantially transparent to at least a portion of solar radiation.

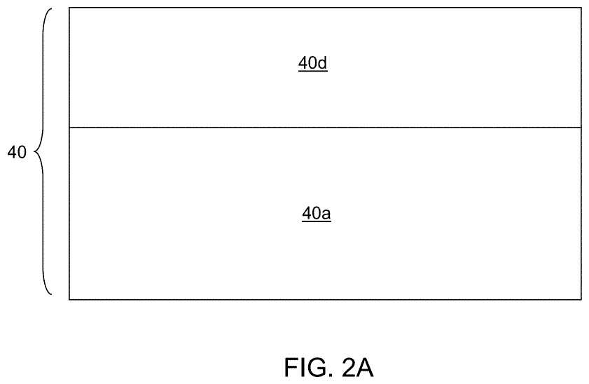

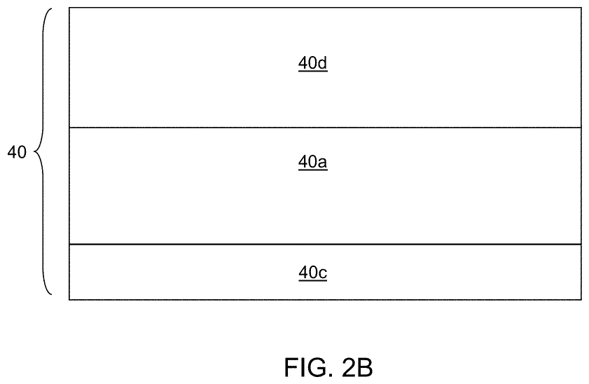

FIGS. 1B, 1D, 2A, and 2B show how n-type semiconductor layer 40 may incorporate one or more sublayers. As discussed above, CIGS solar cells may use CdS for the n-type semiconductor layer 40. Certain embodiments described herein replace a single, monolithic CdS sublayer in the n-type semiconductor layer 40 either partially or completely with a wider bandgap II-IV semiconductor material. One exemplary replacement material is ZnOS. The ZnOS can have a range of compositions (e.g., ZnOₓS₁₋ₓ, where 0<x<1, preferably 0.5<x<0.8, such that the zinc oxysulfide contains at least 25 at. % oxygen). Tuning x adjusts the ratio of oxygen to sulfur in ZnOS. Tuning x may effectively adjust the electron affinity of the ZnOS buffer layer, which may improve the efficiency of the solar cell 10.

As an example, FIG. 1B shows n-type semiconductor layer 40 divided into sublayers 40a and 40b. Sublayer 40a may include ZnOₓS₁₋ₓ, where 0≤x≤1, preferably 0.5≤x≤0.8. Sublayer 40b may include intrinsic ZnO (i-ZnO). Alternatively, sublayer 40b may include ZnO_{y}S_{1-y} material having a different O:S ratio than the ZnOₓS₁₋ₓ material of sublayer 40a. In this configuration, the composition of both sublayers 40a and 40b can be tuned, as discussed in more detail below, by varying the content of oxygen gas flow rate during reactive sputter deposition.

For example, tuning the oxygen content of the ZnOₓS₁₋ₓ sublayer 40a tunes the electron affinity of that sublayer by altering the ratio of oxygen to the sum of oxygen plus sulfur [O:(O+S)] (i.e., x in ZnOₓS₁₋ₓ). Alternatively, or in addition, the power applied to sputtering targets containing Zn and S (e.g., separate Zn and S targets or ZnS, ZnOS, AlZnS, or AlZnOS alloy targets) can be changed to alter the stoichiometry. In either case when the O/(O+S) ratio is tuned in sublayer 40a, the effect is to tune the offset between the conduction band in sublayer 40a and the underlying p-type semiconductor absorber layer 30. As discussed above, tuning the electron affinity can improve the overall efficiency of the solar cell 10.

FIG. 1C shows the effect of tuning the composition of the ZnOS sublayer 40a on solar cell efficiency (Eff (%)). Cell efficiency may relate to “electron affinity,” which refers to the energy difference between the conduction band of the semiconductor material in the subject layer and the vacuum level. As discussed in more detail above, it is generally advantageous to optimize electron affinity in sublayer 40a in order to improve the efficiency of solar cell 10. The curve labeled “CTS” (Cut-Test-Sort) represents experimentally measured data for a predicted O:(O+S) ratio. The curve labeled “SCAPS” (Solar Cell Capacitance Simulator) is simulated data for the same configuration. Both the CTS and SCAPS data are plotted against the predicted atomic ratio of oxygen to the sum of oxygen and sulfur concentrations in sublayer 40a (i.e., O/(O+S)). The latter has been calculated based on a predictive formula relating O₂ flow rate during reactive sputter ZnOS deposition from a ZnS target to the O/(O+S) measured via Energy Dispersive X-ray Spectroscopy (EDS) in single layer films of ZnOS deposited on a substrate. It is assumed that the relationship will hold when the ZnOS is deposited as part of the layered solar cell structures shown in FIGS. 1A and 1B.

FIG. 1C shows how the effectiveness of the ZnOS sublayer 40a as a buffer layer can depend on its composition. More specifically, both CTS measurements and SCAPS simulation data show that solar cell efficiency increases as the O/(O+S) increases from 0.2 to 0.5. The efficiency reaches a plateau (e.g., ≥15%; such as 15.5 to 16.1%) when the O/(O+S) is in the range 0.5 to 0.8 such as 0.55 to 0.75, and decreases when O/(O+S) increases above 0.8. Compositions of sublayer 40a with O/(O+S) outside of an optimal or beneficial range (e.g., O/(O+S) from 0.5-0.8) can exhibit lower efficiency below 15%, likely indicative of non-optimal electron affinity. The non-optimal electron affinity is expected to create a large conduction band offset between sublayer 40a and adjacent layers. Non-optimal electron affinity can lead to losses and an overall degradation of cell 10 efficiency. Therefore, tuning the composition allows for tuning electron affinity, which can improve conduction band alignment and hence efficiency of the solar cell.

FIG. 1D shows the layer 40 of embodiment of FIG. 1B with an additional sublayer 40c deposited under the ZnOS sublayer 40a. Sublayer 40c may be, for example, a thin layer of CdS. In that case, CdS sublayer 40c provides a thin barrier for the overlying ZnOS sublayer 40a. The addition of sublayer 40c can reduce or prevent Zn, or other elements in sublayer 40a, from diffusing into the underlying CIGS layer 30. Sublayer 40c, if relatively thin (e.g., 20 nm or less, such as 2 to 10 nm thickness), can also mitigate collection losses of the cell 10 which would otherwise be caused by a decrease in quantum efficiency due to absorption of short wavelength photons in a relatively thick CdS sublayer (e.g., having a thickness of ≥40 nm).

FIG. 1E shows how reducing the thickness of the CdS sublayer 40c, increases the External Quantum Efficiency (QE) of the solar cell. QE is given in terms of external quantum efficiency without normalization. Around 10% QE loss is expected in the visible spectrum due to reflection and other factors. FIG. 1E represents the thickness of the CdS sublayer in terms of normalized sputtering power used to deposit the CdS sublayer. It is believed that CdS sublayer thickness correlates roughly linearly with sputtering power.

FIG. 1E shows that decreasing sputtering power by roughly 40%, resulting in a comparable decrease in the thickness of the CdS sublayer, for example a reduction of CdS sublayer thickness from about 40 nm to about 24-25 nm, can increase QE in the 400 to 500 nm range by over 10%. This can result in an increased QE, which in turn results in an increase in the short circuit current (“Jsc”) of solar cell 10. However, a thinner CdS layer can result in a decrease in open current voltage (“Voc”) and lead to Fill Factor (“FF”) loss. As discussed above, the addition of the ZnOS sublayer 40a can offset the decrease in Voc and FF loss, and thus facilitate the use of a thinner CdS sublayer 40c which leads to a higher cell efficiency.

FIG. 1F shows a substantial improvement of solar cell 10 efficiency with an addition of a ZnOS sublayer 40a on top of a CdS sublayer 40c over a range of CdS sublayer 40c thicknesses (i.e., as a function of normalized sputtering power). As with FIG. 1E, CdS sublayer 40c thicknesses are given in terms of CdS sputtering power, which varies roughly linearly with CdS thickness. From FIG. 1F, one can see readily that adding ZnOS sublayer 40a (“ZnOS═ON”) over the CdS sublayer 40c increases the efficiency of the cell by approximately 0.2-0.7%, depending on sputtering power (i.e., depending on CdS sublayer thickness). Specifically, efficiencies of 17.2% to 17.8% are shown for CdS sublayer 40c thicknesses of about 25 to about 40 nm with an overlying ZnOS sublayer 40a.

FIG. 1G shows the effect of adding the ZnOS sublayer 40a on Voc of the solar cell 10. As with FIGS. 1E and 1F, CdS sublayer 40c thicknesses are given in terms of sputtering power, which varies roughly linearly with CdS sublayer thickness. From FIG. 1G, one can see readily that adding the ZnOS sublayer 40a on top of CdS sublayer 40c (“ZnOS═ON”) increases Voc by approximately 0.005-0.02 V, depending on the sputtering power (i.e., depending on the CdS sublayer thickness).

FIG. 1H shows the effect of adding the ZnOS sublayer 40a on Jsc of the solar cell 10. As with FIGS. 1E, 1F, and 1G, CdS sublayer 40c thicknesses are given in terms of sputtering power, which varies roughly linearly with CdS thickness. From FIG. 1H, one can see readily that reducing CdS sputtering power (and hence thickness) increases Jsc, which is a consequence of the increased QE in the 400-500 nm range mentioned above. It can also be seen that adding the ZnOS sublayer 40a to layer 40 (“ZnOS═ON”) has a negligible effect on Jsc of solar cell 10. This is due to the wide-bandgap nature of ZnOS compared to CdS.

FIG. 1I shows the effect of adding ZnOS layer (40a and 40b) on the FF of solar cell 10. From FIG. 1I, one can see readily that adding ZnOS to layer 40 (“ZnOS═ON”) improves the FF of solar cell 10. Taken together, FIGS. 1F-1I show that adding a ZnOS sublayer 40a over the CdS sublayer 40c increases efficiency and improves Voc and FF at lower CdS thicknesses.

FIG. 2A shows another variation of the n-type semiconductor layer 40 of the embodiment shown in FIG. 1B in which ZnMgO (i.e., Zn_{1-y}Mg_{y}O, where 0.1≤z≤0.4) sublayer is provided instead of the i-ZnO sublayer 40b of FIG. 1B. In this variation, sublayer 40a may still comprise ZnOₓS₁₋ₓ. Using ZnMgO for sublayer 40d allows tuning of conduction band offsets between the ZnOS in sublayer 40a and the material in the second electrode 50, discussed in more detail below. More specifically, the composition of sublayer 40d may be tuned by altering the power to various targets during sputtering to alter z in the above formula, or the ratio Mg/(Zn+Mg). Tuning the ratio Mg/(Zn+Mg) allows for tuning of the conduction band offsets between the ZnOS sublayer 40a and the second electrode 50. As discussed above, tuning the conduction band offsets between adjacent layers can increase the overall efficiency of solar cell 10.

FIG. 2B shows the n-type semiconductor layer 40 of the embodiment of FIG. 2A with an additional sublayer 40c deposited below the ZnOS sublayer 40a. As discussed above in the context of FIG. 1C, sublayer 40c may be a thin (e.g., 10 to 35 nm) sublayer of CdS. The addition of sublayer 40c can provide a diffusion barrier against Zn and Mg diffusing from layer 40 into the CIGS absorber layer 30. The reduced thickness of sublayer 40c may mitigate collection losses of the cell 10, which would otherwise be caused by a decrease in quantum efficiency due to absorption of short wavelength photons in the CdS sublayer.

Referring again to FIG. 1A, the second (e.g., front side or top) electrode 50 comprises one or more transparent conductive layers 50. The transparent conductive layer 50 is conductive and substantially transparent. The transparent conductive layer 50 can include one or more transparent conductive materials, such as ZnO, indium tin oxide (ITO), Al doped ZnO (“AZO” or “Al—ZnO”), Boron doped ZnO (“BZO”), or a combination or stack of higher resistivity AZO and lower resistivity ZnO, ITO, AZO and/or BZO layers. The second electrode 50 contacts an electrically conductive part (e.g., a metal wire or trace) of an interconnect, such as an interconnect described in U.S. Pat. No. 8,912,429, issued Dec. 16, 2014, which is incorporated herein by reference in its entirety, or any other suitable interconnect that is used in photovoltaic panels.

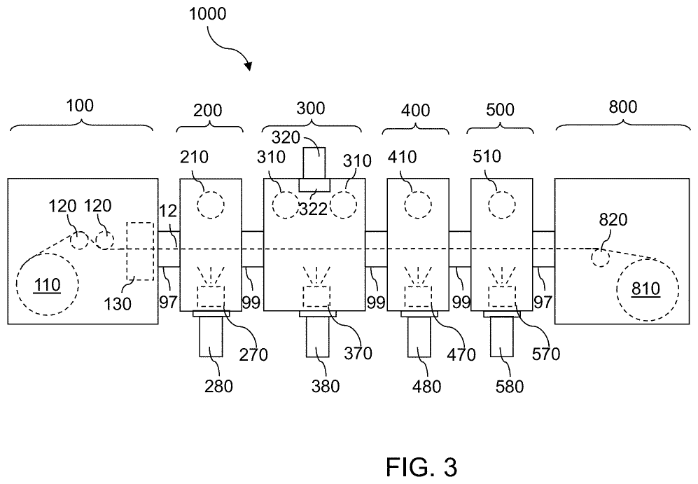

Referring now to FIG. 3, an apparatus 1000 for forming the photovoltaic cell 10 illustrated in FIG. 1A is shown. The apparatus 1000 is a first exemplary modular deposition apparatus that can be used to manufacture the photovoltaic cell illustrated in FIG. 1A. The apparatus 1000 includes an input unit 100, a first process module 200, a second process module 300, a third process module 400, a fourth process module 500, and an output unit 800 that are sequentially connected to accommodate a continuous flow of the substrate 12 in the form of a web foil substrate layer through the apparatus. The modules (100, 200, 300, 400, 500) may comprise the modules described in U.S. Pat. No. 9,303,316, issued on Apr. 5, 2016, incorporated herein by reference in its entirety, or any other suitable modules. The first, second, third, and fourth process modules (200, 300, 400, 500) can be under vacuum by first, second, third, and fourth vacuum pumps (280, 380, 480, 580), respectively. The first, second, third, and fourth vacuum pumps (280, 380, 480, 580) can provide a suitable level of respective base pressure for each of the first, second, third, and fourth process modules (200, 300, 400, 500), which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules (200, 300, 400, 500) is interconnected employing a vacuum connection unit 99, which can include a vacuum tube and an optional slit valve that enables isolation while the substrate 12 is not present. The input unit 100 can be connected to the first process module 200 employing a sealing connection unit 97. The last process module, such as the fourth process module 500, can be connected to the output unit 800 employing another sealing connection unit 97. The sealing connection unit 97 may also be a vacuum connection unit 99 in certain embodiments that require input unit 100 and output unit 800 to be under vacuum. The particular construction of each vacuum connection unit 99 may vary, so long as they are each able to maintain vacuum pressures provided by the first, second, third, and fourth vacuum pumps (280, 380, 480, 580) as the substrate roll 12 moves through apparatus 1000.

The substrate 12 can be a metallic or polymer web foil that is fed into a system of process modules (200, 300, 400, 500) as a web for deposition of material layers thereupon to form the photovoltaic cell 10. The substrate 12 can be fed from an entry side (i.e., at the input module 100), continuously move through the apparatus 1000 without stopping, and exit the apparatus 1000 at an exit side (i.e., at the output module 800). The substrate 12, in the form of a web, can be provided on an input spool 110 provided in the input module 100.

The substrate 12, as embodied as a metal or polymer web foil, is moved throughout the apparatus 1000 by input-side rollers 120, output-side rollers 820, and additional rollers (not shown) in the process modules (200, 300, 400, 500), vacuum connection units 99, or sealing connection units 97, or other devices. Additional guide rollers may be used. Some rollers (120, 820) may be bowed to spread the web (i.e., the substrate 12), some may move to provide web steering, some may provide web tension feedback to servo controllers, and others may be mere idlers to run the web in desired positions.

The input module 100 can be configured to allow continuous feeding of the substrate 12 by adjoining multiple foils by welding, stapling, or other suitable means. Rolls of substrates 12 can be provided on multiple input spools 110. A joinder device 130 can be provided to adjoin an end of each roll of the substrate 12 to a beginning of the next roll of the substrate 12. In one embodiment, the joinder device 130 can be a welder or a stapler. An accumulator device (not shown) may be employed to provide continuous feeding of the substrate 12 into the apparatus 1000 while the joinder device 130 adjoins two rolls of the substrate 12.

The output module 800 can include an output spool 810, which winds the web embodying the photovoltaic cell 10. The photovoltaic cell 10 is the combination of the substrate 12 and the deposited layers (20, 30, 40, 50) thereupon.

Each of deposited layers (20, 30, 40, 50) may be deposited on substrate 12 in a separate process module (200, 300, 400, 500). For example, layer 20 may be deposited in process module 200, layer 30 in process module 300, layer 40 in process module 400, and layer 50 in process module 500. In certain embodiments it may be advantageous to deposit each layer in a unique process module in order to avoid contamination or mixing of layers. In others, it may be advantageous to deposit specific layers in the same process module.

In one embodiment, the substrate 12 may be oriented in one direction in the input module 100 and/or in the output module 800, and in a different direction in the process modules (200, 300, 400, 500). For example, the substrate 12 can be oriented generally horizontally in the input module 100 and the output module 800, and generally vertically in the process module(s) (200, 300, 400, 500). A turning roller or turn bar (not shown) may be provided to change the orientation of the substrate 12, such as between the input module 100 and the first process module 200. In an illustrative example, the turning roller or the turn bar in the input module can be configured to turn the web substrate 12 from an initial horizontal orientation to a vertical orientation. Another turning roller or turn bar (not shown) may be provided to change the orientation of the substrate 12, such as between the last process module (such as the fourth process module 500) and the output module 800. In an illustrative example, the turning roller or the turn bar in the input module can be configured to turn the web substrate 12 from the vertical orientation employed during processing in the process modules (200, 300, 400, 500) to a horizontal orientation.

The input spool 110 and optional output spool 810 may be actively driven and controlled by feedback signals to keep the substrate 12 in constant tension throughout the apparatus 1000. In one embodiment, the input module 100 and the output module 800 can be maintained in the air ambient at all times while the process modules (200, 300, 400, 500) are maintained under vacuum during layer deposition. However, the input module 100 and output module 800 may also be maintained under vacuum.

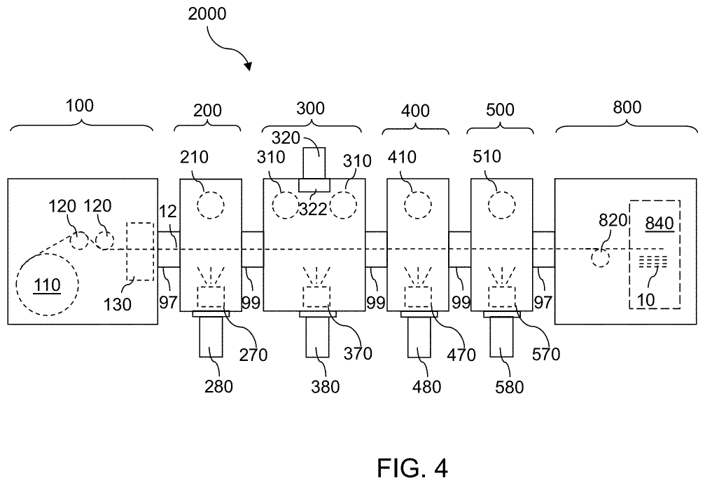

Referring to FIG. 4, a second exemplary modular deposition apparatus 2000 is illustrated, which can be used to manufacture the photovoltaic cell illustrated in FIG. 1A. The second exemplary modular deposition apparatus 2000 includes an alternative output module 800, which includes a cutting apparatus 840 instead of an output spool 810. The web containing the photovoltaic cells 10 can be fed into the cutting apparatus 840 in the output module 800, and can be cut into discrete sheets of photovoltaic cells 10 instead of being rolled onto an output spool 810. The discrete sheets of photovoltaic cells are then interconnected using interconnects to form a photovoltaic panel (i.e., a solar module) which contains an electrical output.

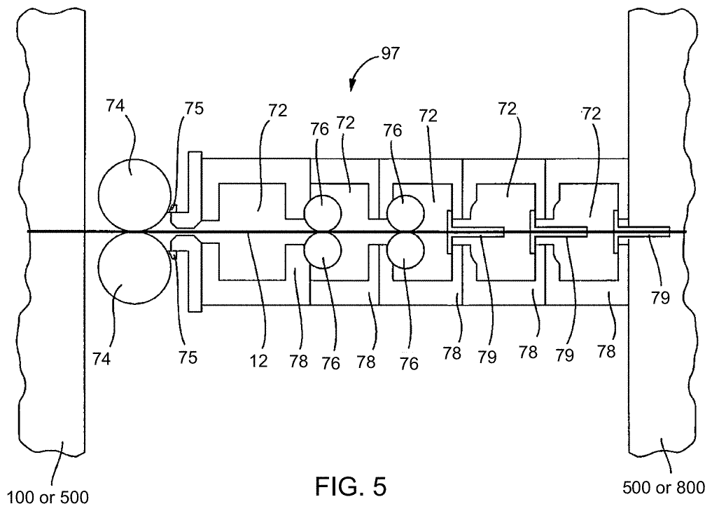

Referring to FIG. 5, an exemplary sealing connection unit 97 is illustrated. The unit 97 may comprise the sealing unit described in U.S. Pat. No. 9,303,316, issued on Apr. 5, 2016, incorporated herein by reference in its entirety, or any other suitable sealing unit. The sealing connection unit 97 is configured to allow the substrate 12 to pass out of a preceding unit (such as the input unit 100 or the last processing chamber such as the fourth process module 500) and into a subsequent unit (such as the first process module 200 or the output unit 800), while impeding the passage of gasses such as atmospheric gasses or processing gasses into or out of the units that the sealing connection unit 97 is adjoined to. The sealing connection unit 97 can include multiple isolation chambers 72.

The staged isolation chambers 72 can be configured to maintain internal pressures that graduate from atmospheric on a first side of the sealing connection unit 97 (such as the side of the input module 100 or the output module 800) to a high vacuum on the second side of the sealing connection unit 97 opposite of the first side (such as the side of the first process module 200 or the last process module 500). Multiple isolation chambers 72 can be employed to ensure that the pressure difference at any sealing surface is generally less than the pressure difference between atmospheric pressure and the high vacuum inside the process module.

The substrate 12 enters the sealing unit 97 between two external nip rollers 74. Each of the isolation chambers 72 of the sealing connection unit 97 can be separated by an internal divider 78, which is an internal wall among the isolation chambers 72. A pair of internal nip rollers 76, similar in function and arrangement to that of the external rollers 74, may be provided proximate to the internal dividers 78 between some of the neighboring internal chambers 72. The passage between the internal rollers 76 is generally closed off by rolling seals between the internal rollers 76 and the substrate 12. The internal dividers 78 may include curved sockets or contours that are configured to receive internal rollers 76 of a similar radius of curvature. The passage of gasses from one isolation chamber 72 to a neighboring, lower pressure internal chamber 72 may be reduced by a simple surface to surface contact between the internal roller 76 and the divider 78.

In other embodiments, a seal such as a wiper seal 75 may be provided for some or all of the internal rollers 76 to further reduce the infiltration of gasses into neighboring isolation chambers 72. The internal rollers 76 may be freely spinning rollers, or may be powered to control the rate of passage of the substrate 12 through the sealing connection unit 97. Between other chambers 72, the passage of gasses between neighboring chambers 72 may be limited by parallel plate conductance limiters 79. The parallel plate conductance limiters 79 are generally flat, parallel plates that are arranged parallel to the surface of the substrate 12 and are spaced apart a distance slightly larger than the thickness of the substrate 12. The parallel plate conductance limiters 79 allow the substrate to pass between the chambers 72 while limiting the passage of gasses between chambers 72.

Referring back to FIGS. 3 and 4, each of the first, second, third, and fourth process modules (200, 300, 400, 500) can deposit a respective material layer to form the photovoltaic cell 10 (shown in FIG. 1A) as the substrate 12 passes through the first, second, third, and fourth process modules (200, 300, 400, 500) sequentially. The modules (100, 200, 300, 400, 500) may comprise first, second, third, and fourth heaters (270, 370, 470, 570) configured to heat the substrate 12 to a corresponding appropriate deposition temperature.

Optionally, one or more additional process modules (not shown) may be added between the input module 100 and the first process module 200 to sputter a back side protective layer on the back side of the substrate 12 before deposition of the first electrode 20 in the first process module 200. Further, one or more barrier layers may be sputtered over the front surface of the substrate 12 prior to deposition of the first electrode 20. Alternatively or additionally, one or more process modules (not shown) may be added between the first process module 200 and the second process module 300 to sputter one or more adhesion layers between the first electrode 20 and the p-type semiconductor layer 30 including a chalcogen-containing compound semiconductor material.

The first process module 200 includes a first sputtering target 210, which includes the material of the first electrode 20 in the photovoltaic cell 10 illustrated in FIG. 1A. The first heater 270 can be provided to heat the web substrate 12 to an optimal temperature for deposition of the first electrode 20. In one embodiment, a plurality of first sputtering targets 210 and a plurality of first heaters 270 may be employed in the first process module 200. In one embodiment, the at least one first sputtering target 210 can be mounted on dual cylindrical rotary magnetron(s), or planar magnetron(s) sputtering targets, or RF sputtering targets. In one embodiment, the at least one first sputtering target 210 can include a molybdenum target, a molybdenum-sodium, and/or a molybdenum-sodium-oxygen target, as described in U.S. Pat. No. 8,134,069, incorporated herein by reference in its entirety.

The portion of the substrate 12 on which the first electrode 20 is deposited is moved into the second process module 300. A p-type chalcogen-containing compound semiconductor material is deposited to form the p-type semiconductor layer 30, such as a sodium doped CIGS absorber layer. In one embodiment, the p-type chalcogen-containing compound semiconductor material can be deposited employing reactive alternating current (AC) magnetron sputtering in a sputtering atmosphere that includes argon and a chalcogen-containing gas at a reduced pressure. In one embodiment, multiple metallic component targets 310 including the metallic components of the p-type chalcogen-containing compound semiconductor material can be provided in the second process module 300.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 310 can include an alloy of all non-metallic materials in the chalcogen-containing compound semiconductor material to be deposited. For example, if the chalcogen-containing compound semiconductor material is a CIGS material, the metallic component targets 310 can include an alloy of copper, indium, and gallium. More than two targets 310 may be used. The second heater 370 can be a radiation heater that maintains the temperature of the web substrate 12 at the deposition temperature, which can be in a range from 400° C. to 800° C., such as a range from 500° C. to 700° C., which is preferable for CIGS deposition.

At least one chalcogen-containing gas source 320 (such as a selenium evaporator) and at least one gas distribution manifold 322 can be provided on the second process module 300 to provide a chalcogen-containing gas into the second process module 300. While FIGS. 2 and 3 schematically illustrate a second process module 300 including two metallic component targets 310, a single chalcogen-containing gas source 320, and a single gas distribution manifold 322, multiple instances of the chalcogen-containing gas source 320 and/or the gas distribution manifold 322 can be provided in the second process module 300.

The chalcogen-containing gas provides chalcogen atoms that are incorporated into the deposited chalcogen-containing compound semiconductor material. For example, if a CIGS material is to be deposited for the p-type semiconductor layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be a selenium evaporator, such as an effusion cell that can be heated to generate selenium vapor.

The chalcogen incorporation during deposition of the chalcogen-containing compound semiconductor material determines the properties and quality of the chalcogen-containing compound semiconductor material in the p-type semiconductor layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-type semiconductor layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 310.

In one embodiment, each metallic component target 310 can be employed with a respective magnetron (not expressly shown) to deposit a chalcogen-containing compound semiconductor material with a respective composition. In one embodiment, the composition of the metallic component targets 310 can be gradually changed along the path of the substrate 12 so that a graded chalcogen-containing compound semiconductor material can be deposited in the second process module 300. For example, if a CIGS material is deposited as the chalcogen-containing compound semiconductor material of the p-type semiconductor layer 30, the atomic percentage of gallium of the deposited CIGS material can increase as the substrate 12 progresses through the second process module 300. In this case, the p-type CIGS material in the p-type semiconductor layer 30 of the photovoltaic cell 10 can be graded such that the band gap of the p-type CIGS material increases with distance from the interface between the first electrode 20 and the p-type semiconductor layer 30.

In one embodiment, the total number of metallic component targets 310 may be in a range from 3 to 20. In an illustrative example, the composition of the deposited chalcogen-containing compound semiconductor material (e.g., the p-type CIGS material absorber 30) can be graded such that the band gap of the p-type CIGS material varies (e.g., increases or decreases gradually or in steps) with distance from the interface between the first electrode 20 and the p-type semiconductor layer 30. For example, the band gap can be about 1 eV at the interface with the first electrode 20, and can be about 1.3 eV at the interface with subsequently formed n-type semiconductor layer 40.

The second process module 300 includes a deposition system for deposition of a chalcogen-containing compound semiconductor material for forming the p-type semiconductor layer 30. As discussed above, the deposition system includes a vacuum enclosure attached to a vacuum pump (such as at least one second vacuum pump 380), and a sputtering system comprising at least one sputtering target (such as the at least one metallic component target 310, for example a Cu—In—Ga target) located in the vacuum enclosure and at least one respective magnetron. The sputtering system is configured to deposit a material including at least one component of a chalcogen-containing compound semiconductor material (i.e., the non-chalcogen metallic component(s) of the chalcogen-containing compound semiconductor material) over the substrate 12 in the vacuum enclosure. In other words, the module 300 is a reactive sputtering module in which the chalcogen gas (e.g., selenium vapor) from gas distribution manifolds 322 reacts with the metal (e.g., Cu—In—Ga) sputtered from the targets 310 to form the chalcogen-containing compound semiconductor material (e.g., CIGS) layer 30 over the substrate 12.

In an illustrative example, the chalcogen-containing compound semiconductor material can comprise a copper indium gallium selenide, and the at least one sputtering target (i.e., the metallic component targets 310) can comprise materials selected from copper, indium, gallium, and alloys thereof (e.g., Cu—In—Ga alloy, CIG). In one embodiment, the chalcogen-containing gas source 320 can be configured to supply a chalcogen-containing gas selected from gas phase selenium and hydrogen selenide (H₂Se). In one embodiment, the chalcogen-containing gas can be gas phase selenium, i.e., vapor phase selenium, which is evaporated from a solid source in an effusion cell.

While the present disclosure is described employing an embodiment in which metallic component targets 310 are employed in the second process module 300, embodiments are expressly contemplated herein in which each, or a subset, of the metallic component targets 310 is replaced with a pair of two sputtering targets (such as a copper target and an indium-gallium alloy target), or with a set of three sputter targets (such as a copper target, an indium target, and a gallium target).

Generally speaking, the chalcogen-containing compound semiconductor material can be deposited by providing a substrate 12 in a vacuum enclosure attached to a vacuum pump 380, providing a sputtering system comprising at least one sputtering target 310 located in the vacuum enclosure and at least one respective magnetron located inside a cylindrical target 310 or behind a planar target (not explicitly shown), and providing a gas distribution manifold 322 having a supply side and a distribution side. The chalcogen-containing compound semiconductor can be deposited by sputtering a material including at least one component (i.e., the non-chalcogen component) of a chalcogen-containing compound semiconductor material onto the substrate 12 while flowing a chalcogen-containing gas (e.g., Se vapor) into the vacuum chamber through the gas distribution manifold 322.

The portion of the substrate 12 on which the first electrode 20 and the p-type semiconductor layer 30 are deposited is subsequently passed into the third process module 400. An n-type semiconductor material is deposited in the third process module 400 to form the n-type semiconductor layer 40 illustrated in the photovoltaic cell 10 of FIG. 1A. The third process module 400 can include, for example, a third sputtering target 410 (e.g., a CdS target), a magnetron (not expressly shown) and an O₂ gas inlet port for reactive sputtering. The third sputtering target 410 can include, for example, a rotating AC magnetron, an RF magnetron, or a planar magnetron.

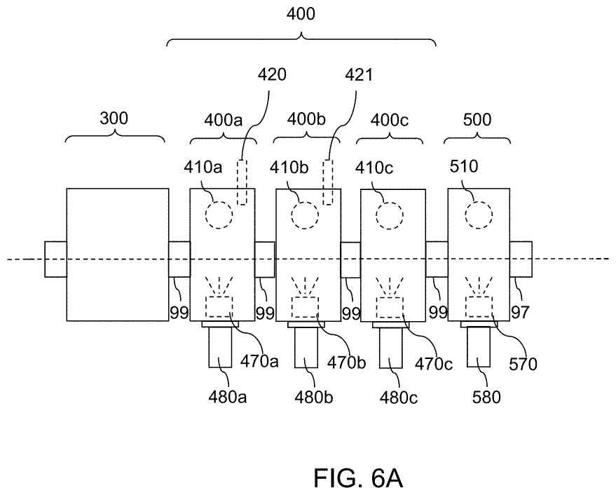

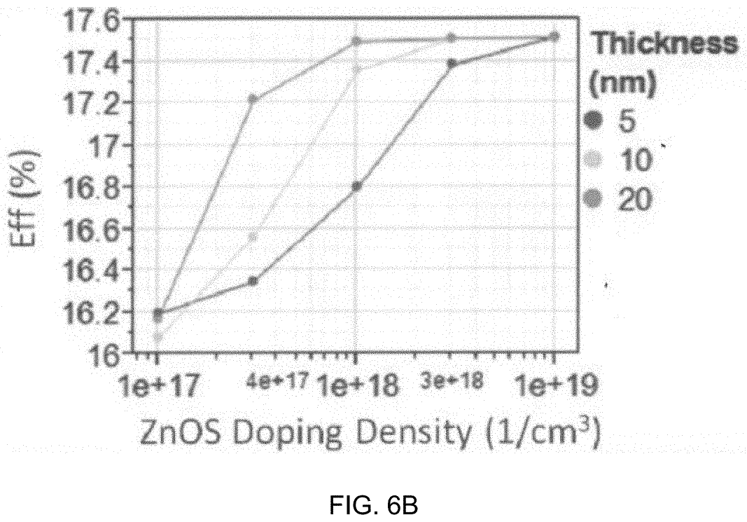

FIG. 6A shows how third processing module 400 may be sub-divided into multiple processing submodules 400a, 400b, and 400c, in order to separately create multiple sublayers in layer 40. Although FIG. 6A shows three processing submodules 400a, 400b, and 400c, it is to be understood that this number is merely exemplary and that any suitable number of processing submodules may be used (e.g., one processing submodule for each sublayer of layer 40). Each processing submodule, 400a, 400b, and 400c includes at least one separate sputtering target 410a, 410b, and 410c. Each of the sputtering targets 410a, 410b, and 410c may correspond to one or more sublayers 40a, 40b, 40c, and/or 40d in FIGS. 1B, 1D, 2A, and 2B.

For example, in the case in which the sublayer configuration of FIG. 1B is deposited, there may be only two processing submodules 400a and 400b. Sputtering target 410a in processing submodule 400a would include material suitable for depositing the desired material for sublayer 40a, or some combination of Zn, S, and optionally O. The Zn target may be present for reactive sputtering with sulfur and/or oxygen, or may be combined in a single ZnS or ZnOS target 410a. In order to reactively sputter the desired composition of ZnOₓS₁₋ₓ to create sublayer 40a, O₂ gas is supplied to processing submodule 400a through an O₂ inlet port 420 from an oxygen source (e.g., an oxygen tank) in the desired concentration. As discussed above, controlling the supply of O₂ gas determines the quantity x in the stoichometry of ZnOₓS₁₋ₓ in sublayer 40a. Sputtering target 410b in processing submodule 400b would include material suitable for depositing the desired material for sublayer 40b, such as a Zn target for reactively sputtering ZnO, or a ZnO target for non-reactively sputtering ZnO, or a ZnS or ZnOS target for reactively sputtering ZnOS for a desired ZnOₓS₁₋ₓ layer composition that may be different from sublayer 40a. Processing submodule 400b may also have the capability of introducing O₂ gas through optional port 421 in order to supply oxygen gas to create the desired stoichiometry i-ZnO in sublayer 40b. In the case in which the two sublayer n-type layer 40 of FIG. 1B is deposited, sub-processing module 400c may be absent or may be present but unused.

In the case in which the sublayer configuration of FIG. 1D is deposited, processing submodules 400a, 400b, and 400c would be used. Sputtering target 410a in processing submodule 400a would include material suitable for depositing the desired material for sublayer 40c, or some combination of Cd and S. The Cd and S may be combined in a single CdS target 410a. Sputtering target 410b in processing submodule 400a would include material suitable for depositing the desired material for sublayer 40a, or some combination of Zn and S. The Zn, S, and optionally O may be combined in a single ZnS or ZnOS target 410b. In order to reactively sputter the desired composition of ZnOₓS₁₋ₓ to create sublayer 40a, O₂ gas is supplied to processing submodule 400b through an O₂ inlet port 421 from an oxygen source (e.g., an oxygen tank) in the desired concentration. As discussed above, controlling the supply of O₂ gas determines the quantity x in the stoichometry of ZnOₓS₁₋ₓ in sublayer 40a. Sputtering target 410c in processing submodule 400c would include material suitable for depositing the desired material for sublayer 40b, again a combination of Zn and O or ZnO, or ZnOS with a composition different from sublayer 40a. Processing submodule 400c may also have the capability of introducing O₂ gas in order to supply oxygen content to create the desired stoichiometry in sublayer 40b.

In the case in which the sublayer configuration of FIG. 2A is deposited, there also may be only two processing submodules 400a and 400b. Sputtering target 410a in processing submodule 400a would include material suitable for depositing the desired material for sublayer 40a, or some combination of Zn and S. The Zn may be combined in a single ZnS or ZnOS target 410a. In order to deposit the desired composition of ZnOₓS₁₋ₓ to create sublayer 40a, O₂ gas is supplied to processing submodule 400a through an O₂ inlet port 420 from an oxygen source (e.g., an oxygen tank) in the desired concentration. As discussed above, controlling the supply of O₂ gas determines the quantity x in the stoichometry of ZnOₓS₁₋ₓ in sublayer 40a. Sputtering target 410b in processing submodule 400b would include material suitable for depositing the desired material for sublayer 40d some combination of Zn, Mg, and/or oxygen. The Zn and Mg may be present as separate targets, or may be combined in a single ZnMg target, ZnO and MgO targets, or a ZnMgO target 410b. Processing submodule 400b may also have the capability of introducing O₂ gas through inlet port 421 in order to supply oxygen gas to achieve the desired stoichiometry in the Zn_{1-y}Mg_{y}O sublayer 40d. Processing submodule 400c may be absent or may be present but unused in this case.

In the case in which the sublayer configuration of FIG. 2B is deposited, processing submodules 400a, 400b, and 400c would be used. Sputtering target 410a in processing submodule 400a would include material suitable for depositing the desired material for sublayer 40c, or some combination of Cd and S. The Cd and S may be combined in a single CdS target 410a. Sputtering target 410b in processing submodule 400b would include material suitable for depositing the desired material for sublayer 40a, or some combination of Zn, S, and optionally O. The Zn, S and optionally O may be combined in a single ZnS or ZnOS target 410b. In order to reactively sputter the desired composition of ZnOₓS₁₋ₓ to create sublayer 40a, O₂ gas is supplied to processing submodule 400b in the desired concentration. As discussed above, controlling the supply of O₂ gas determines the quantity x in the stoichometry of ZnOₓS₁₋ₓ in sublayer 40a. Sputtering target 410c in processing submodule 400c would include material suitable for depositing the desired material for sublayer 40d in a ZnMg target, ZnO and MgO targets, or a ZnMgO target. Processing submodule 400c may also have the capability of introducing O₂ gas through an O₂ inlet port from an oxygen source (e.g., an oxygen tank) in order to supply oxygen gas to create the desired composition of Zn_{1-y}Mg_{y}O in sublayer 40d.

The portion of the substrate 12 on which the first electrode 20, the p-type semiconductor layer 30, and the n-type semiconductor layer 40 are deposited is subsequently passed into the fourth process module 500. A transparent conductive oxide material is deposited in the fourth process module 500 to form the second electrode comprising a transparent conductive layer 50 illustrated in the photovoltaic cell 10 of FIG. 1A. The fourth process module 500 can include, for example, a fourth sputtering target 510 and a magnetron (not expressly shown). The fourth sputtering target 510 can include, for example, a ZnO, AZO or ITO target and a rotating AC magnetron, an RF magnetron, or a planar magnetron. A transparent conductive oxide layer 50 is deposited over the material stack (30, 40) including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 12 passes into the output module 800. The substrate 12 can be wound onto the output spool 810 (which may be a take up spool) as illustrated in FIG. 3, or can be sliced into photovoltaic cells using a cutting apparatus 840 as illustrated in FIG. 4.

FIG. 6B is a plot of solar cell 10 efficiency as a function of Al doping and thickness of the ZnOS sublayer 40a which shows an improvement in solar cell 10 efficiency with increased aluminum doping density and thickness for the configuration of the n-type semiconductor layer shown in FIG. 1D. The results shown in FIG. 6B are derived from SCAPS simulation. As shown in FIG. 6B, the efficiency increases with Al doping density from around 16.2 to 17.5%, where it tends to plateau. The doping density at which the 17.5% efficiency plateau is reached appears to depend on the thickness (5 nm, 10 nm, or 20 nm, see legend) of the ZnOS sublayer 40a. In particular, the plateau is reached at a relatively low doping density of 1×10¹⁸ cm⁻³ for ZnOS films of 20 nm thickness, while it appears to require three times as much n-type dopant to reach the plateau in a ZnOS sublayer 40a of 5 nm thickness. Thus, sublayer 40a preferably has an aluminum doping density (e.g., concentration) of at least 1×10¹⁷ cm³, such as 1×10¹⁸ cm⁻³ to 1×10²¹ cm⁻³, and a thickness of 10 to 40 nm.

The Al doped ZnOS and/or ZnMgO sublayers can be sputtered using targets in which Al is added to the zinc containing sputtering targets (e.g., ZnS, ZnOS, ZnMgO, etc.) For example, it is possible to add Al to the sputtering targets 410a and 410b for creating sublayers 40a and 40d, respectively, of FIG. 2A. Adding Al to the sputtering target in the range of 0.1-1 wt. % of the sputtering material also tends to increase the sputtering rate. Increasing the sputtering rate may create thicker layers, which may improve overall cell efficiency, as shown in FIG. 6B. It is to be understood that addition of Al may be provided in this manner to any of the sputtering targets shown in FIG. 3, 4, or 6A to deposit any of the layers or sublayers described herein.

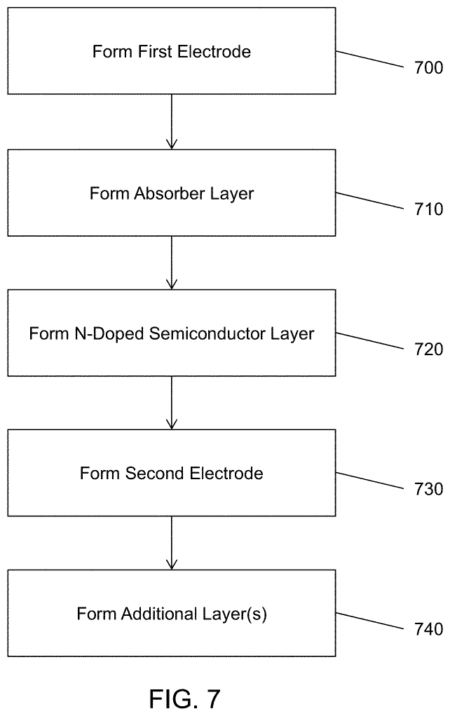

FIG. 7 is a process flow diagram illustrating a sputter deposition method, according to various embodiments of the present disclosure. The method may involve using a deposition system as discussed above with regard to FIGS. 3, 4, and 6A. Referring to FIGS. 3, 4, 6A, and 7, in step 700, the method may include forming a first or back side electrode on a substrate. For example, the first electrode may be deposited on the substrate while the substrate moves through the first process module 200.

In step 710, an absorber layer (i.e., p-type semiconductor layer) may be formed on the first electrode. For example, the absorber layer may be deposited on the substrate while the substrate moves through the second process module 300.

In step 720, an n-type semiconductor layer may be formed on the absorber layer. For example, the n-type semiconductor layer may be deposited on the substrate while the substrate moves through the third process module 400.

In step 730, a second electrode may be formed on an n-type semiconductor layer. For example, the second electrode may be deposited on the substrate while the substrate moves through the fourth process module 500.

The method may optionally include step 740, wherein additional layers may be formed over the substrate. For example, optional step 740 may include forming an anti-reflection layer and/or a protective layer on the second electrode.

While sputtering was described as the preferred method for depositing all layers onto the substrate, some layers may be deposited by MBE, CVD, evaporation, plating, etc.

According to various embodiments, method of manufacturing a solar cell includes depositing a first electrode over a substrate under vacuum, depositing at least one p-type semiconductor absorber layer over the first electrode without breaking the vacuum, wherein the p-type semiconductor absorber layer comprises a copper indium selenide (CIS) based alloy material, sputter depositing an n-type semiconductor layer over the at least one p-type semiconductor absorber layer to form zinc oxysulfide having at least 25 atomic percent oxygen in the n-type semiconductor layer without breaking the vacuum, and depositing a second electrode over the n-type semiconductor layer without breaking the vacuum.

Depositing the n-type semiconductor layer may include depositing a doped or undoped ZnOₓS₁₋ₓ sublayer, where 0.5≤x≤0.8. The method may include depositing an intrinsic ZnO layer over the ZnOₓS₁₋ₓ sublayer. Depositing the second electrode may include depositing the second electrode over the intrinsic ZnO layer. The method may include depositing a CdS sublayer over the at least one p-type semiconductor absorber layer in which case depositing the doped or undoped ZnOₓS₁₋ₓ sublayer may include depositing the ZnOₓS₁₋ₓ sublayer over the CdS sublayer. A thickness of the CdS sublayer may be less than 40 nm, and the solar cell may have an external quantum efficiency greater than 0.7 from absorption of photons in a range from 400 to 450 nm. For example, the thickness of the CdS sublayer may be 10 to 30 nm.

The method may further include depositing a Zn_{1-y}Mg_{y}O sublayer over the ZnOₓS₁₋ₓ sublayer in which case depositing the second electrode may include depositing the second electrode over the Zn_{1-y}Mg_{y}O sublayer. The method may further include depositing a CdS sublayer over the at least one p-type semiconductor absorber layer, in which case depositing the doped or undoped ZnOₓS₁₋ₓ sublayer may include depositing the ZnOₓS₁₋ₓ sublayer over the CdS sublayer.

Sputter depositing the n-type semiconductor layer may include sputtering the zinc oxysulfide from a target containing zinc, sulfur, and optionally oxygen. For example, sputtering the zinc oxysulfide may include reactively sputtering from a zinc sulfide or zinc oxysulfide target in an O₂ flow that yields a value of x between 0.5 and 0.8 in the ZnOₓS₁₋ₓ sublayer.

The sputter depositing the n-type semiconductor layer may employ a zinc, sulfur, and optionally oxygen containing sputtering target having an Al content in the range of 0.1 to 1.0 wt. The zinc oxysulfide in the n-type semiconductor layer may have a thickness of 10 to 40 nm and an aluminum doping density of at least 1×10¹⁷ cm⁻³.

Other embodiments include a solar cell containing a substrate, a first electrode located over the substrate, and at least one p-type semiconductor absorber layer located over the first electrode. The p-type semiconductor absorber layer includes a copper indium selenide (CIS) based alloy material. The solar cell further includes an n-type semiconductor layer located over the at least one p-type semiconductor absorber layer and including zinc oxysulfide and a second electrode located over the n-type semiconductor layer. The n-type semiconductor layer may include a doped or undoped ZnOₓS₁₋ₓ sublayer, where 0.5≤x≤0.8. A CdS sublayer may be located over the at least one p-type semiconductor absorber layer, wherein the ZnOₓS₁₋ₓ sublayer may be located over the CdS sublayer. A thickness of the CdS sublayer may be less than 40 nm and the solar cell may have an external quantum efficiency greater than 0.7 from absorption of photons in a range from 400 to 500 nm. The thickness of the CdS sublayer may be 10 to 30 nm.

A Zn_{1-y}Mg_{y}O sublayer may be located over the ZnOₓS₁₋ₓ sublayer. The second electrode may be located over the Zn_{1-y}Mg_{y}O sublayer. In addition, a CdS sublayer may be located over the at least one p-type semiconductor absorber layer and the ZnOₓS₁₋ₓ sublayer may be located over the CdS sublayer. Sputter depositing the zinc oxysulfide may employ a zinc oxysulfide sputter target having an Al content in the range of 0.1-1.0 wt % such that the Zn_{1-y}Mg_{y}O sublayer is doped with aluminum and has aluminum doping density of at least 1×10¹⁸ cm⁻³, such as 1×10¹⁸ cm⁻³ to 1×10²¹ cm⁻³.

The zinc oxysulfide in the n-type semiconductor layer may have a thickness of 10 to 40 nm and an aluminum doping density of at least 1×10¹⁷ cm⁻³, such as 1×10¹⁸ cm⁻³ to 1×10²¹ cm³. The solar cell may have an efficiency greater than or equal to 16.1%, such as 16.1 to 17.5%.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the present invention.

What is claimed is:

1. A method of manufacturing a solar cell, comprising:
depositing a first electrode over a substrate under vacuum;
depositing at least one p-type semiconductor absorber layer over the first electrode without breaking the vacuum, wherein the p-type semiconductor absorber layer comprises a copper indium selenide (CIS) based alloy material;
sputter depositing an n-type semiconductor layer from a target comprising at least zinc and sulfur the at least one p-type semiconductor absorber layer to form zinc oxysulfide without breaking the vacuum; and
depositing a second electrode over the n-type semiconductor layer without breaking the vacuum.

2. The method of claim 1, wherein depositing the n-type semiconductor layer comprises depositing a doped or undoped ZnOₓS₁₋ₓ sublayer, where 0.5≤x≤0.8.

3. The method of claim 1, wherein sputtering the zinc oxysulfide comprises reactively sputtering from a zinc sulfide target or a zinc oxysulfide target in an O₂ flow that yields the ZnOₓS₁₋ₓ sublayer where 0.5≤x≤0.8.

4. The method of claim 1, wherein:
sputter depositing the n-type semiconductor layer employs a target containing zinc and sulfur, or zinc, sulfur and oxygen;
the sputtering target has an aluminum content in the range of 0.1 to 1.0 wt. %; and
the zinc oxysulfide in the n-type semiconductor layer has a thickness of 10 to 40 nm and the aluminum doping density of at least 1×10¹⁷ cm⁻³.

5. The method of claim 2, further comprising depositing an intrinsic ZnO sublayer over the ZnOₓS₁₋ₓ sublayer, wherein depositing the second electrode comprises depositing the second electrode over the intrinsic ZnO sublayer.

6. The method of claim 5, further comprising depositing a CdS sublayer over the at least one p-type semiconductor absorber layer, wherein depositing the doped or undoped ZnOₓS₁₋ₓ sublayer comprises depositing the ZnOₓS₁₋ₓ sublayer over the CdS sublayer.

7. The method of claim 6, wherein a thickness of the CdS sublayer is less than 40 nm, and the solar cell has an external quantum efficiency greater than 0.7 from absorption of photons in a range from 400 to 450 nm.

8. The method of claim 6, wherein a thickness of the CdS sublayer is 10 to 30 nm.

9. The method of claim 2, further comprising depositing a Zn_{1-y}Mg_{y}O sublayer over the ZnOₓS₁₋ₓ sublayer, wherein depositing the second electrode comprises depositing the second electrode over the Zn_{1-y}Mg_{y}O sublayer.

10. The method of claim 9, further comprising depositing a CdS sublayer over the at least one p-type semiconductor absorber layer, wherein the depositing the doped or undoped ZnOₓS₁₋ₓ sublayer comprises depositing the ZnOₓS₁₋ₓ sublayer over the CdS sublayer.

11. A solar cell, comprising:
a substrate;
a first electrode located over the substrate;
at least one p-type semiconductor absorber layer located over the first electrode, wherein the p-type semiconductor absorber layer comprises a copper indium selenide (CIS) based alloy material;
an n-type semiconductor layer located over the at least one p-type semiconductor absorber layer and comprising Al-doped zinc oxysulfide having an Al doping density of at least 1×10¹⁷ cm⁻³; and
a second electrode located over the n-type semiconductor layer.

12. The solar cell of claim 11, wherein the n-type semiconductor layer comprises a doped or undoped ZnOₓS₁₋ₓ sublayer, where 0.5≤x≤0.8.

13. The solar cell of claim 12, further comprising a CdS sublayer located over the at least one p-type semiconductor absorber layer, wherein the ZnOₓS₁₋ₓ sublayer is located over the CdS sublayer.

14. The solar cell of claim 13, wherein a thickness of the CdS sublayer is less than 40 nm and the solar cell has an external quantum efficiency greater than 0.7 from absorption of photons in a range from 400 to 500 nm.

15. The solar cell of claim 13, wherein a thickness of the CdS sublayer is 10 to 30 nm.

16. The solar cell of claim 12, further comprising a Zn_{1-y}Mg_{y}O sublayer located over the ZnOₓS₁₋ₓ sublayer, wherein the second electrode is located over the Zn_{1-y}Mg_{y}O sublayer.

17. The solar cell of claim 16, further comprising a CdS sublayer located over the at least one p-type semiconductor absorber layer, wherein the ZnOₓS₁₋ₓ sublayer is located over the CdS sublayer.

18. The solar cell of claim 16, wherein the Zn_{1-y}Mg_{y}O sublayer is doped with aluminum and has the aluminum doping density of at least 1×10¹⁸ cm⁻³.

19. The solar cell of claim 11, wherein the zinc oxysulfide in the n-type semiconductor layer has a thickness of 10 to 40 nm.

20. The solar cell of claim 19, wherein the Al-doped zinc oxysulfide has the aluminum doping density of at least 1×10¹⁸ cm⁻³.
